(19) United States
(12) Patent Application Publication
(10) Pub. No.: US 2026/0052996 A1
(43) Pub. Date: Feb. 19, 2026

(54) SEMICONDUCTOR PACKAGE

(71) Applicant: Samsung Electronics Co., Ltd., Suwon-si (KR)

(72) Inventor: Gi Hun Lee, Suwon-si (KR)

(21) Appl. No.: 19/202,144

(22) Filed: May 8, 2025

(30) Foreign Application Priority Data
Aug. 14, 2024 (KR) 10-2024-0109222

(51) Int. Cl. H01L 23/00; H01L 23/498

(52) U.S. Cl. CPC H01L 23/562; H01L 23/49827; H01L 24/16; H01L 24/32; H01L 24/73; H01L 2224/16225; H01L 2224/32225; H01L 2224/73204

(57) ABSTRACT

A semiconductor package with reduced contact defect and enhanced reliability is provided. The semiconductor package includes a substrate including an insulating layer and a through-via extending through the insulating layer, a magnet within the insulating layer and spaced apart from the through-via, a semiconductor chip on the substrate, and a magnetic layer on the semiconductor chip and overlapping with at least a portion of the magnet in a vertical direction relative to an upper surface of the substrate.

### CROSS-REFERENCE TO RELATED APPLICATION(S)

This application claims priority under 35 U.S.C. 119 from Korean Patent Application No. 10-2024-0109222 filed on Aug. 14, 2024 in the Korean Intellectual Property Office, the contents of which is herein incorporated by reference in its entirety.

### BACKGROUND

The present disclosure relates to a semiconductor package.

As an electronic product is miniaturized, slimmed down, and made more dense, a printed circuit package substrate is becoming smaller and slimmer.

In this regard, as the printed circuit package substrate becomes thinner and the package product becomes more compact, warpage of a semiconductor package is becoming a problem. In some instances, the warpage of the semiconductor package may be due to differences between heat expansion coefficients of a semiconductor chip, an epoxy molding compound, and the printed circuit package substrate in the manufacturing process. Such warpage of the semiconductor package may cause poor contact of the semiconductor chip mounted on the printed circuit package substrate, thereby having a negative impact on the reliability of the semiconductor package.

### SUMMARY

Some embodiments of the present disclosure provides a semiconductor package with reduced contact defects and enhanced reliability.

Embodiments of the present disclosure are not limited to the above-mentioned embodiment. Other embodiments and advantages according to the present disclosure that are not mentioned may be understood based on following descriptions, and may be more clearly understood based on embodiments according to the present disclosure. Further, it will be easily understood that the embodiments and advantages according to the present disclosure may be realized using means shown in the claims and combinations thereof.

According to some embodiments of the present disclosure, a semiconductor package includes a substrate including an insulating layer and a through-via extending through the insulating layer, a magnet within the insulating layer and spaced apart from the through-via, a semiconductor chip on the substrate, and a magnetic layer on the semiconductor chip and overlapping with at least a portion of the magnet in a vertical direction relative to an upper surface of the substrate.

According to some embodiments of the present disclosure, a semiconductor package includes a substrate extending in a first direction and a second direction different from the first direction, a plurality of magnets within the substrate and arranged along the first direction and the second direction, a semiconductor chip on the substrate and extending in a third direction and a fourth direction different from the third direction, and a magnetic layer on an upper surface of the semiconductor chip, and extending in the third direction and the fourth direction, wherein the magnetic layer is configured to be affected by a magnetic force of the plurality of magnets.

According to some embodiments of the present disclosure, a semiconductor package includes a substrate including a first insulating layer, a first through-via extending through the first insulating layer, a second insulating layer on the first insulating layer, a second through-via extending through the second insulating layer, a shielding film at least partially surrounding the second through-via, and a pad on the second insulating layer, a magnet within the second insulating layer and spaced apart from the second through-via and the shielding film, a semiconductor chip on the substrate, a contact member between the substrate and the semiconductor chip and in contact with the semiconductor chip and the pad, an underfill between the substrate and the semiconductor chip, and a magnetic layer on the semiconductor chip overlapping at least a portion of the magnet in a vertical direction relative to an upper surface of the substrate, wherein a thickness of the first insulating layer is greater than a thickness of the second insulating layer.

It should be noted that embodiments of the present disclosure are not limited to those described above, and other embodiments of the present disclosure will be apparent from the following description.

### BRIEF DESCRIPTION OF DRAWINGS

FIG. 1 is a plan view of a semiconductor package according to some embodiments of the present disclosure.

FIG. 2 is a plan view of a semiconductor chip of the semiconductor package of FIG. 1.

FIG. 3 is a cross-sectional side view of the semiconductor package of FIG. 1 taken along line I-I.

FIG. 4 is a cross-sectional view of a substrate of the semiconductor package of FIG. 1 taken along line I-I.

FIGS. 5 and 6 are side views illustrating an effect of the semiconductor package according to some embodiments of the present disclosure.

FIGS. 7 to 9 are a plan view and cross-sectional side views illustrating a semiconductor package according to some embodiments of the present disclosure.

FIGS. 10 and 11 are cross-sectional side views illustrating a semiconductor package according to some embodiments of the present disclosure.

FIGS. 12 and 13 are a plan view and a cross-sectional side view illustrating a semiconductor package according to some embodiments of the present disclosure.

FIGS. 14 to 16 are plan views and a cross-sectional side view illustrating a semiconductor package according to some embodiments of the present disclosure.

FIG. 17 is a plan view illustrating a semiconductor package according to some embodiments of the present disclosure.

FIG. 18 is a flow chart illustrating a method for manufacturing a substrate according to some embodiments of the present disclosure.

FIGS. 19 to 25 are cross-sectional side views of intermediate structures corresponding to intermediate steps of a method for manufacturing a substrate according to some embodiments of the present disclosure.

FIG. 26 is a flow chart illustrating a method of manufacturing a semiconductor package according to some embodiments.

FIGS. 27 to 29 are cross-sectional side views of intermediate structures corresponding to intermediate steps of a method for manufacturing a substrate according to some embodiments.

### DETAILED DESCRIPTIONS

Advantages and features of the present disclosure, and a method of achieving the advantages and features will become apparent with reference to embodiments described below in detail together with the accompanying drawings. However, the embodiments of the present disclosure are not limited to the example embodiments as disclosed herein, but may be implemented in various different forms. Thus, these embodiments are set forth only to make the present disclosure, and to inform the scope of the present disclosure to those of ordinary skill in the technical field to which the present disclosure belongs, and the present disclosure is only defined by the scope of the claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Hereinafter, example embodiments of the present disclosure will be explained in detail with reference to the accompanying drawings.

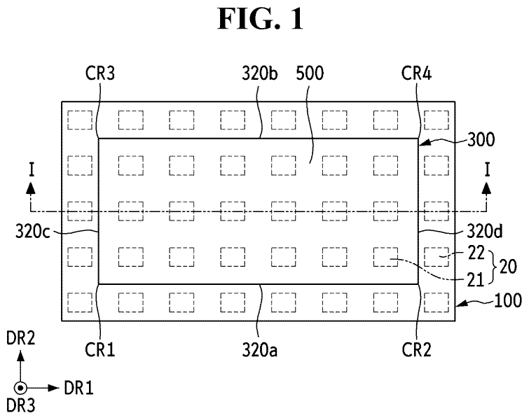

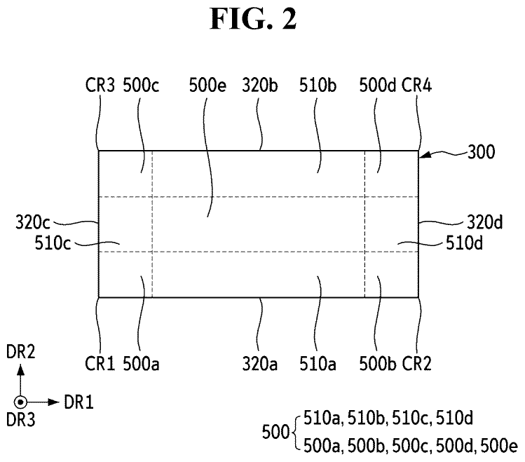

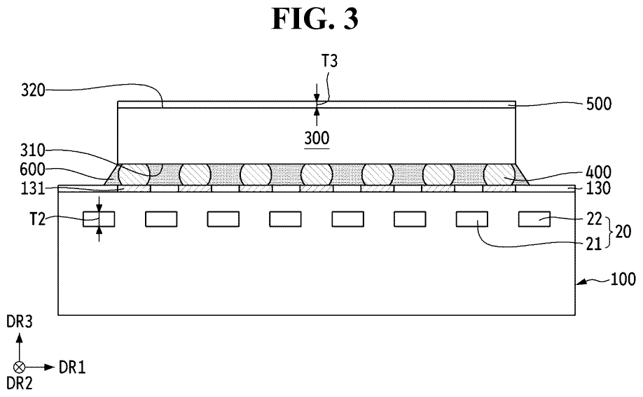

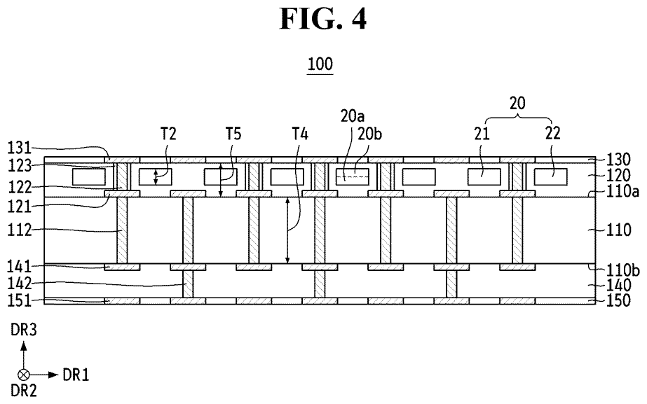

FIG. 1 is a plan view of a semiconductor package according to some embodiments of the present disclosure. FIG. 2 is a plan view of a semiconductor chip of the semiconductor package of FIG. 1. FIG. 3 is a cross-sectional side view of the semiconductor package of FIG. 1 taken along line I-I. FIG. 4 is a cross-sectional view of a substrate of the semiconductor package of FIG. 1 taken along line I-I.

Referring to FIGS. 1 to 4, a semiconductor package according to some embodiments of the present disclosure includes a substrate 100, a semiconductor chip 300, a plurality of second magnets 20, and a magnetic layer 500. As shown in FIG. 3, in some embodiments, the semiconductor package may further include a plurality of contact members 400 and an underfill 600.

The substrate 100 extends in a first direction DR1 and a second direction DR2, which is different from the first direction DR1. The substrate 100 may be a semiconductor package substrate on which a semiconductor chip 300 is mounted. The substrate 100 may be, for example, at least one of a printed circuit board (PCB), a flip chip ball grid array (FCBGA), a flip chip chip scale package (FCCSP), and an interposer. However, embodiments of the present disclosure are not limited thereto.

Referring to FIG. 4, in some embodiments, the substrate 100 may include a first insulating layer 110, a plurality of first through-vias 112, a first wiring 121, a second wiring 141, a second insulating layer 120, a plurality of second through-vias 122, a third insulating layer 140, a plurality of third through-vias 142, a plurality of first pads 131, a plurality of second pads 151, a first protective layer 130, and a second protective layer 150.

The first insulating layer 110 may extend in the first direction DR1 and the second direction DR2. In some embodiments, the first insulating layer 110 may be a core layer of a printed circuit board (PCB). In some embodiments, the first insulating layer 110 may be a copper clad laminate (CCL) having copper clads respectively stacked on both opposing surfaces. In some embodiments, the first insulating layer 110 may include glass fiber or prepreg (PPG).

The first insulating layer 110 may include a first surface 110a and a second surface 110b that are opposite to each other in a third direction DR3. The third direction DR3 may be a thickness direction of the first insulating layer 110.

The plurality of first through-vias 112 may be disposed within the first insulating layer 110. The plurality of first through-vias 112 may be spaced apart from each other in the first direction DR1. The plurality of first through-vias 112 may extend through the first insulating layer 110. The plurality of first through-vias 112 may extend from the first surface 110a of the first insulating layer 110 to the second surface 110b of the first insulating layer 110 in the third direction DR3. In some embodiments, the plurality of first through-vias 112 may include copper (Cu).

The first wiring 121 and the second wiring 141 may be disposed on the first insulating layer 110. Specifically, the first wiring 121 may be disposed on the first surface 110a of the first insulating layer 110 and the second wiring 141 may be disposed on the second surface 110b of the first insulating layer 110. The first wiring 121 and the second wiring 141 may be disposed on the plurality of first through-vias 112. The first wiring 121 and the second wiring 141 may overlap the plurality of first through-vias 112 in the third direction DR3. The first wiring 121 and the second wiring 141 may be in contact with the plurality of first through-vias 112. The first wiring 121 and the second wiring 141 may be electrically connected to each other via the plurality of first through-vias 112. In some embodiments, the first wiring 121 and the second wiring 141 may include copper (Cu).

The second insulating layer 120 may be disposed on the first surface 110a of the first insulating layer 110. The second insulating layer 120 may be disposed on the plurality of first pads 131. In some embodiments, the second insulating layer 120 may be a prepreg (PPG) layer of a printed circuit board (PCB). In some embodiments, the second insulating layer 120 may include glass fiber or prepreg (PPG).

The first insulating layer 110 may have a fourth thickness T4 in the third direction DR3. The second insulating layer 120 may have a fifth thickness T5 in the third direction DR3. In some embodiments, in order to control the warpage of the substrate 100, the fourth thickness T4 of the first insulating layer 110 may be greater than the fifth thickness T5 of the second insulating layer 120. For example, in some embodiments, the fourth thickness of the first insulating layer 110 may be at least twice that of the fifth thickness T5 of the second insulating layer 120.

The plurality of second through-vias 122 may be disposed within the second insulating layer 120. The plurality of second through-vias 122 may be disposed on the first wiring 121. The plurality of second through-vias 122 may be spaced apart from each other in the first direction DR1. The plurality of second through-vias 122 may extend through the second insulating layer 120. The plurality of second through-vias 122 may extend from the first wiring 121 to an upper surface of the second insulating layer 120 in the third direction DR3. The plurality of second through-vias 122 may contact the first wiring 121. In some embodiments, the plurality of second through-vias 122 may include copper (Cu).

The third insulating layer 140 may be disposed on the second surface 110b of the first insulating layer 110. The third insulating layer 140 may be disposed on the second wirings 141. The third insulating layer 140 may be a prepreg (PPG) layer of a printed circuit board PCB. In some embodiments, the third insulating layer 140 may include glass fiber or prepreg (PPG).

The plurality of third through-vias 142 may be disposed within the third insulating layer 140. The plurality of third through-vias 142 may be disposed on the second wiring 141. The plurality of third through-vias 142 may be spaced apart from each other in the first direction DR1. The plurality of third through-vias 142 may extend through the third insulating layer 140. The plurality third through-vias 142 may extend from the second wiring 141 to a bottom surface of the third insulating layer 140 in the third direction DR3. The plurality of third through-vias 142 may be in contact with the second wiring 141. In some embodiments, the plurality of third through-vias 142 may include copper (Cu).

The plurality of first pads 131 may be disposed on the second insulating layer 120. Each of the plurality of first pads 131 may be respectively disposed on the plurality of second through-vias 122. The plurality of first pads 131 may be spaced apart from each other in the first direction DR1. The plurality of first pads 131 may overlap the the plurality of second through-vias 122 in the third direction DR3. The plurality of first pads 131 may be in contact with the plurality of second through-vias 122. The plurality of first pads 131 may be electrically connected to the first wiring 121 via the plurality of second through-vias 122.

The plurality of second pads 151 may be disposed on the third insulating layer 140. Each of the plurality of second pads 151 may be respectively disposed on the plurality of third through-vias 142. The plurality of second pads 151 may be spaced apart from each other in the first direction DR1. The plurality of second pads 151 may overlap with the plurality of third through-vias 142 in the third direction DR3. The plurality of second pads 151 may be in contact with the plurality of third through-vias 142. The plurality second pads 151 may be electrically connected to the second wiring 141 through the plurality of third through-vias 142. In some embodiments, each of the first pads 131 and the second pads 151 may include copper (Cu).

The first protective layer 130 may be disposed on the second insulating layer 120. A portion of the first protective layer 130 may be disposed between adjacent first pads 131. The first protective layer 130 may cover at least a portion of an upper surface of the second insulating layer 120 on which the plurality of first pads 131 is not disposed. The first protective layer 130 may be in contact with a side surface of one or more of the plurality of first pads 131. As shown in FIG. 4, an upper surface of the first protective layer 130 and an upper surface of each of the plurality of first pads 131 are illustrated as being coplanar with each other. However, embodiments of the present disclosure are not limited thereto. For example, in some embodiments, a vertical level of the upper surface of the first protective layer 130 may be higher than a vertical level of one or more of the upper surfaces of the first pads 131 based on the first surface 110a of the first insulating layer 110.

The second protective layer 150 may be disposed on the third insulating layer 140. A portion of the second protective layer 150 may be disposed between adjacent second pads 151. The second protective layer 150 may cover at least a portion of an upper surface of the third insulating layer 140 on which the plurality of second pads 151 is not disposed. The second protective layer 150 may be in contact with a side surface of one or more of the plurality of second pads 151. As shown in FIG. 4, a bottom surface of the second protective layer 150 and a bottom surface of each of the plurality of second pads 151 are illustrated as being coplanar with each other. However, embodiments of the present disclosure are not limited thereto. For example, in some embodiments, a vertical level of the bottom surface of the second protective layer 150 may be lower than a vertical level of one or more of the bottom surfaces of the second pads 151 based on the second surface 110b of the first insulating layer 110.

In some embodiments, each of the first protective layer 130 and the second protective layer 150 may be a solder resist layer of a printed circuit board (PCB). In some embodiments, each of the first protective layer 130 and the second protective layer 150 may include an epoxy resin.

Referring again to FIG. 1 and FIG. 2, in some embodiments, the plurality of second magnets 20 may be disposed within the substrate 100. The plurality of second magnets 20 may be arranged along the first direction DR1 and the second direction DR2. The plurality of second magnets 20 may be spaced from each other in the first direction DR1 and the second direction DR2. The plurality of second magnets 20 may overlap each other in the first direction DR1 and the second direction DR2.

Each of the second magnets 20 may include a third sub-magnet 21 and a fourth sub-magnet 22. As described in further detail below, in some embodiments, the third sub-magnet 21 may overlap with the semiconductor chip 300 in the third direction DR3. In some embodiments, the fourth sub-magnet 22 may not overlap with the semiconductor chip 300 in the third direction DR3.

Referring again to FIG. 4, the plurality of second magnets 20 may be disposed within the second insulating layer 120. The plurality of second magnets 20 may be spaced from the plurality of second through-vias 122. Each of the second magnets 20 may include a third portion 20a and a fourth portion 20b that are opposite to each other in the third direction DR3. An end of the third portion 20a has a third magnetic polarity. An end of the fourth portion 20b has a fourth magnetic polarity. The third magnetic polarity and the fourth magnetic polarity are opposite magnetic polarity to each other. For example, in some embodiments, when the third magnetic polarity is a north (N) pole, the fourth magnetic polarity is a south(S) pole.

Each of the second magnets 20 may include at least one of a ferrite magnet, a neodymium magnet, a samarium-cobalt magnet, an alnico magnet, and a flexible magnet.

In some embodiments, the substrate 100 may further include a second shielding film 123. The second shielding film 123 may be disposed within the second insulating layer 120. The second shielding film 123 may be disposed between the plurality second through-vias 122 and the plurality of second magnets 20. The second shielding film 123 may be spaced apart from the plurality of second magnets 20. The second shielding film 123 may at least partially surround a side surface of each of the plurality of second through-vias 122. The second shielding film 123 may extend in the third direction DR3 and along the side surfaces of each of the plurality of second through-vias 122. In some embodiments, the second shielding film 123 may include a magnetic shielding material, for example, at least one of Mu-metal, permalloy, and silicon steel.

As each of the second through-vias 122 is disposed between adjacent second magnets 20, the second through-vias 122 and current flowing through the second through-vias 122 may be affected by a magnetic force between adjacent second magnets 20. In some embodiments, the second shielding film 123 may shield the magnetic force directed toward the respective second through-vias 122, and thus, a semiconductor package with improved reliability may be provided.

The semiconductor chip 300 is disposed on the substrate 100. The semiconductor chip 300 may overlap the substrate 100 in the third direction DR3. The semiconductor chip 300 may extend in a fourth direction (e.g., a first direction DR1) and a fifth direction (e.g., a second direction DR2). In other words, the fourth direction may be the same direction as the first direction DR1, or may be a different direction therefrom, and the fifth direction may be the same direction as the second direction DR2, or may be a different direction therefrom. In following descriptions, example embodiments in which the fourth direction is the same direction as the first direction DR1, and the fifth direction is the same direction as the second direction DR2, are described.

The semiconductor chip 300 may include a third surface 310 and a fourth surface 320 that are opposite to each other in the third direction DR3. In some embodiments, the fourth surface 320 of the semiconductor chip 300 may be an upper surface of the semiconductor chip 300.

As shown in FIG. 1 and FIG. 2, the fourth surface 320 of the semiconductor chip 300 may include a first edge 320a and a second edge 320b that extend in the fourth direction DR1 and are spaced apart from each other in the fifth direction DR2. The fourth surface 320 of the semiconductor chip 300 may further include a third edge 320c and a fourth edge 320d that extend in the fifth direction DR2 and spaced from each other in the fourth direction DR1. Each of the first edge 320a and the second edge 320b may be connected to the third edge 320c and the fourth edge 320d. The first edge 320a, the second edge 320b, the third edge 320c, and the fourth edge 320d may define a perimeter of the fourth surface 320 of the semiconductor chip 300.

The fourth surface 320 of the semiconductor chip 300 may include a first corner CR1, a second corner CR2, a third corner CR3, and a fourth corner CR4.

The first corner CR1 of the semiconductor chip 300 may be a corner connecting the first edge 320a and the second edge 320b to each other. The second corner CR2 of the semiconductor chip 300 may be a corner connecting the second edge 320b and the fourth edge 320d to each other. The third corner CR3 of the semiconductor chip 300 may be a corner connecting the first edge 320a and the fourth edge 320d to each other. The fourth corner CR4 of the semiconductor chip 300 may be a corner connecting the second edge 320b and the third edge 320c to each other.

In some embodiments, the semiconductor chip 300 may be a memory semiconductor chip. For example, in some embodiments, the semiconductor chip 300 may be a volatile memory such as a Dynamic Random Access Memory (DRAM) or a Static Random Access Memory (SRAM), or a nonvolatile memory such as a flash memory, a Phase-change Random Access Memory (PRAM), a Magnetoresistive Random Access Memory (MRAM), a Ferroelectric Random Access Memory (FeRAM), or a Resistive Random Access Memory (RRAM).

In some embodiments, the semiconductor chip 300 may be a logic semiconductor chip. For example, in some embodiments, the semiconductor chip 300 may be an application processor (AP) such as a Central Processing Unit (CPU), a Graphics Processing Unit (GPU), a Field-Programmable Gate Array (FPGA), a digital signal processor, an encryption processor, a microprocessor, a microcontroller, an Application-Specific IC (ASIC), etc. However, embodiments of the present disclosure are not limited thereto.

As shown in FIG. 3, in some embodiments, the plurality of contact members 400 may be disposed between the substrate 100 and the semiconductor chip 300. The plurality of contact members 400 may be disposed on the third surface 310 of the semiconductor chip 300. The plurality of contact members 400 may be arranged along the fourth direction DR1 and the fifth direction DR2. The plurality of contact members 400 may be spaced apart from each other in the fourth direction DR1 and the fifth direction DR2. Each of the contact members 400 may be in contact with a respective first pad 131. The plurality of contact members 400 may electrically connect the substrate 100 and the semiconductor chip 300 to each other.

Each of the contact members 400 may be a micro bump including a low melting point metal, for example, tin (Sn) and a tin (Sn) alloy. The number, spacing, arrangement, etc. of the plurality of contact members 400 are not limited to those illustrated and may vary depending on the design.

The magnetic layer 500 may be disposed on the fourth surface 320 of the semiconductor chip 300. The magnetic layer 500 may cover at least a portion of the fourth surface 320 of the semiconductor chip 300. The magnetic layer 500 may extend from the third edge 320c of the semiconductor chip 300 to the fourth edge 320d of the semiconductor chip 300 in the fourth direction DR1. The magnetic layer 500 may extend from the first edge 320a of the semiconductor chip 300 to the second edge 320b of the semiconductor chip 300 in the fifth direction DR2. The magnetic layer 500 may extend from the first corner CR1 of the semiconductor chip 300 in the fourth direction DR1 and the fifth direction DR2. The magnetic layer 500 may contact the fourth surface 320 of the semiconductor chip 300. The magnetic layer 500 may overlap the third sub-magnet 21 of the plurality of second magnets 20 in the third direction DR3.

As shown in FIG. 2, in some embodiments, the magnetic layer 500 may include a first magnetic layer 500a, a second magnetic layer 500b, a third magnetic layer 500c, and a fourth magnetic layer 500d. The magnetic layer 500 may include a first connection magnetic layer 510a, a second connection magnetic layer 510b, a third connection magnetic layer 510c, and a fourth connection magnetic layer 510d. In some embodiments, the magnetic layer 500 may include a fifth magnetic layer 500e.

The first magnetic layer 500a may extend from the first corner CR1 of semiconductor chip 300 and along the first edge 320a and the second edge 320b of the semiconductor chip 300. The second magnetic layer 500b may extend from the second corner CR2 of the semiconductor chip 300 and along the first edge 320a and the fourth edge 320d of the semiconductor chip 300. The third magnetic layer 500c may extend from the third corner CR3 of the semiconductor chip 300 and along the second edge 320b and the third edge 320c of the semiconductor chip 300. The fourth magnetic layer 500d may extend from the fourth corner CR4 of the semiconductor chip 300 and along the second edge 320b and the fourth edge 320d of the semiconductor chip 300. The first magnetic layer 500a may be spaced apart from the second magnetic layer 500b, the third magnetic layer 500c, and the fourth magnetic layer 500d. The second magnetic layer 500b may be spaced apart from the third magnetic layer 500c and the fourth magnetic layer 500d. The third magnetic layer 500c may be spaced apart from the fourth magnetic layer 500d.

The first connection magnetic layer 510a may extend along the first edge 320a of the semiconductor chip 300. The first connection magnetic layer 510a may connect the first magnetic layer 500a and the second magnetic layer 500b to each other. The second connection magnetic layer 510b may extend along the second edge 320b of the semiconductor chip 300. The second connection magnetic layer 510b may connect the third magnetic layer 500c and the fourth magnetic layer 500d to each other. The third connection magnetic layer 510c may extend along the third edge 320c of the semiconductor chip 300. The third connection magnetic layer 510c may connect the first magnetic layer 500a and the third magnetic layer 500c to each other. The fourth connection magnetic layer 510d may extend along the fourth edge 320d of the semiconductor chip 300. The fourth connection magnetic layer 510d may connect the second magnetic layer 500b and the fourth magnetic layer 500d to each other.

The fifth magnetic layer 500e may be spaced apart from each of the first edge 320a and the second edge 320b of the semiconductor chip 300 in the fifth direction DR2. The fifth magnetic layer 500e may be spaced apart from each of the third edge 320c and the fourth edge 320d of the semiconductor chip 300 in the fourth direction DR1. The fifth magnetic layer 500e may be connected to each of the first connection magnetic layer 510a, the second connection magnetic layer 510b, the third connection magnetic layer 510c, and the fourth connection magnetic layer 510d.

The magnetic layer 500 is affected by a magnetic force of the plurality of second magnets 20. In order for the magnetic layer 500 to be affected by the magnetic force of the plurality of second magnets 20, the plurality of second magnets 20 may be disposed within a predetermined distance from the magnetic layer 500 in the plan view.

The plurality of second magnets 20 may have a second thickness T2 in the third direction DR3. The magnetic layer 500 may have a third thickness T3 in the third direction DR3. In order for the magnetic layer 500 to be affected by the magnetic force of the plurality of second magnets 20, the second thickness T2 of the plurality of second magnets 20 may be greater than the third thickness T3 of the magnetic layer 500.

The magnetic layer 500 may include at least one of a ferromagnetic material, for example, iron (Fe), nickel (Ni), and cobalt (Co). The magnetic layer 500 may include an adhesive material, for example, an epoxy resin.

As shown in FIG. 3, in some embodiments, the underfill 600 may be disposed between the substrate 100 and the semiconductor chip 300. The underfill 600 may fill a space between the substrate 100 and the semiconductor chip 300. The underfill 600 may at least partially surround the side surfaces of each of the contact members 400. The underfill 600 may contact the substrate 100, the third surface 310 of the semiconductor chip 300, and one or more of the contact members 400. In some embodiments, the underfill 600 may include an insulating polymer material, such as epoxy mold compound (EMC).

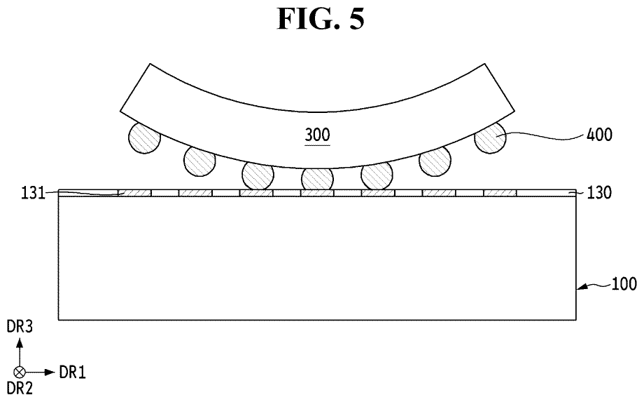

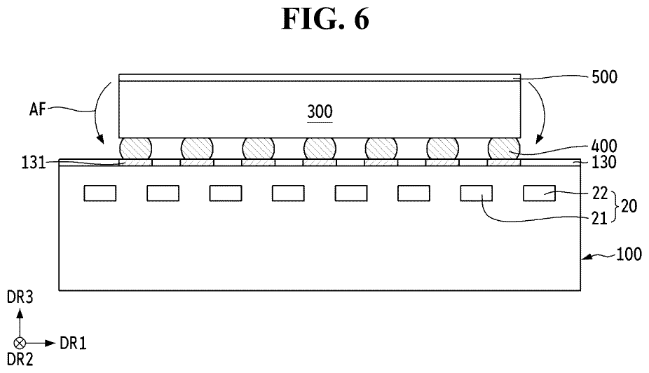

FIGS. 5 and 6 are side views illustrating an effect of a semiconductor package according to some embodiments of the present disclosure. Specifically, FIG. 5 is a side view illustrating warpage of a semiconductor package that does not include a magnet and a magnetic layer. FIG. 6 is a side view illustrating an effect of a semiconductor package including a magnet 20 and a magnetic layer 500.

Referring to FIG. 5, the semiconductor chip 300 may be warped. The warpage of the semiconductor chip 300 may be caused, for example, due to a difference between the heat expansion coefficient of different materials during a process of mounting the semiconductor chip 300 on the substrate 100. In some instances, the semiconductor chip 300 may be warped in a downward convex shape from the substrate 100 (e.g., a smile shape) as shown in FIG. 5. In other instances, unlike as shown in FIG. 5, the semiconductor chip 300 may be warped in an upward convex shape from the substrate 100 (e.g., a frown or shape).

Referring to FIG. 6, the plurality of second magnets 20 is disposed within the substrate 100. The magnetic layer 500 is disposed on the semiconductor chip 300. An attraction force (referred to as “AF” in FIG. 6) may work between the plurality of second magnets 20 and the magnetic layer 500 (e.g. magnetic force). Specifically, in some embodiments, since the magnetic layer 500 includes, for example, ferromagnetic material, the plurality of second magnets 20 may pull the magnetic layer 500 toward the substrate 100. As the magnetic layer 500 is pulled toward the substrate 100, the warpage of the semiconductor chip 300 may be controlled. As the warpage of the semiconductor chip 300 is controlled, the number of contact members 400 in contact with the plurality of first pads 131 of the substrate 100 may increase. Thus, a semiconductor package having reduced contact defects and enhanced reliability may be provided.

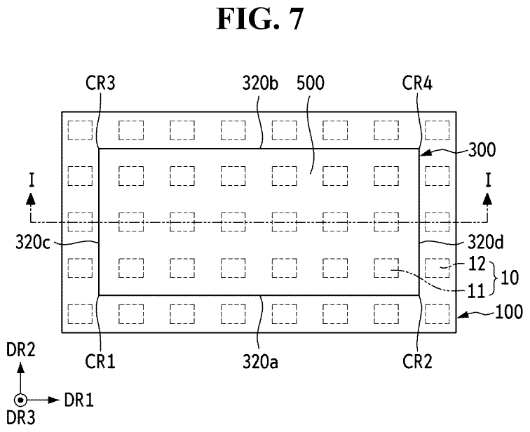

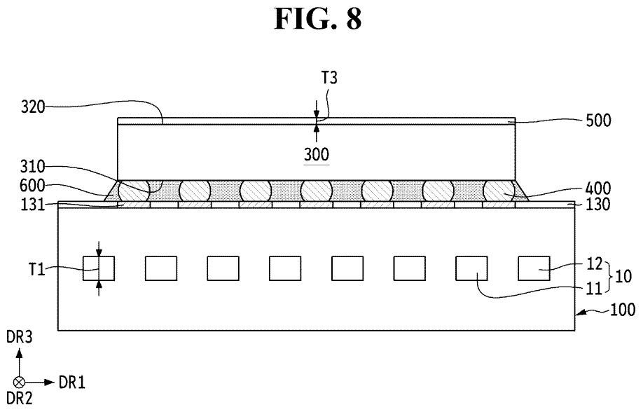

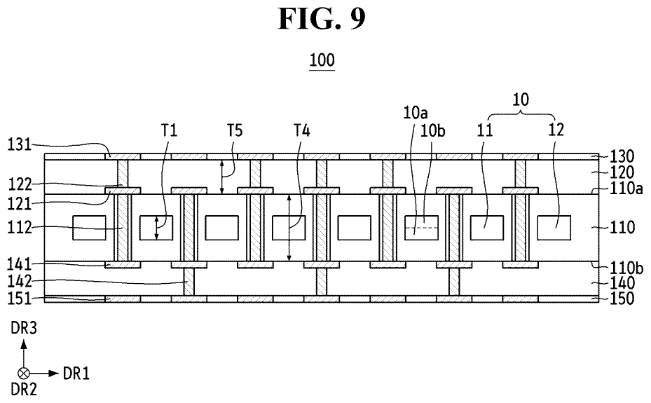

FIGS. 7 to 9 illustrate a semiconductor package according to some embodiments of the present disclosure. Specifically, FIG. 7 is a plan view of a semiconductor package according to some embodiments of the present disclosure. FIG. 8 is a cross-sectional side view of the semiconductor package FIG. 7 taken along line I-I. FIG. 9 is a cross-sectional side view of the substrate of the semiconductor package of FIG. 7 taken along line I-I. For convenience of description, duplicate contents with respect to the semiconductor package described herein and shown in FIGS. 1 to 4 will be briefly described or descriptions thereof may be omitted, and differences therebetween will be described.

Referring to FIGS. 7 to 9, the semiconductor package according to some embodiments of the present disclosure may include a plurality of first magnets 10. In some embodiments, the semiconductor package of the present disclosure may not include a plurality of second magnets 20, for example, as shown in FIG. 4.

The plurality of first magnets 10 are disposed in the substrate 100. The plurality of first magnets 10 are arranged along the first direction DR1 and the second direction DR2. The plurality of first magnets 10 may be spaced apart from each other in the first direction DR1 and the second direction DR2. The plurality of first magnets 10 may overlap each other in the first direction DR1 and the second direction DR2.

The first magnet 10 may include a first sub-magnet 11 and a second sub-magnet 12. The first sub-magnet 11 may overlap the semiconductor chip 300 in the third direction DR3. The second sub-magnet 12 may not overlap the semiconductor chip 300 in the third direction DR3.

The plurality of first magnets 10 may be disposed in the first insulating layer 110. The plurality of first magnets 10 may be spaced apart from the plurality of first through-vias 112. Each of the first magnets 10 may include a first portion 10a and a second portion 10b that are opposite to each other in the third direction DR3. The second portion 10b may be closer to the magnetic layer 500 than the first portion 10a. An end of the first portion 10a has a first magnetic polarity. An end of the second portion 10b has a second magnetic polarity. The first magnetic polarity and the second magnetic polarity are opposite magnetic polarity to each other. For example, in some embodiments, when the first magnetic polarity is a north (N) pole, the second magnetic polarity is a south(S) pole.

The plurality of first magnets 10 may include at least one of a ferrite magnet, a neodymium magnet, a samarium-cobalt magnet, an alnico magnet, and a flexible magnet.

In some embodiments, the substrate 100 of the semiconductor package of the present disclosure may further include a first shielding film 113. The first shielding film 113 may be disposed within the first insulating layer 110. The first shielding film 113 may be disposed between the plurality of first through-vias 112 and the plurality of first magnets 10. The first shielding film 113 may be spaced apart from the plurality of first magnet s10. The first shielding film 113 may at least partially surround the side surfaces of each of the plurality of first through-vias 112. The first shielding film 113 may extend from the first surface 110a of the first insulating layer 110 to the second surface 110b of the first insulating layer 110 in the third direction DR3. The first shielding film 113 may extend along the side surfaces of each of the plurality of first through-vias 112 in the third direction DR3. In some embodiments, the first shielding film 113 may include a magnetic shielding material, for example, at least one of Mu-metal, permalloy, and silicon steel.

The plurality of first magnets 10 may have a first thickness T1 in the third direction DR3. In order for the magnetic layer 500 to be affected by the magnetic force of the plurality of first magnets 10, the first thickness T1 of the plurality of first magnets 10 may be greater than the third thickness T3 of the magnetic layer 500.

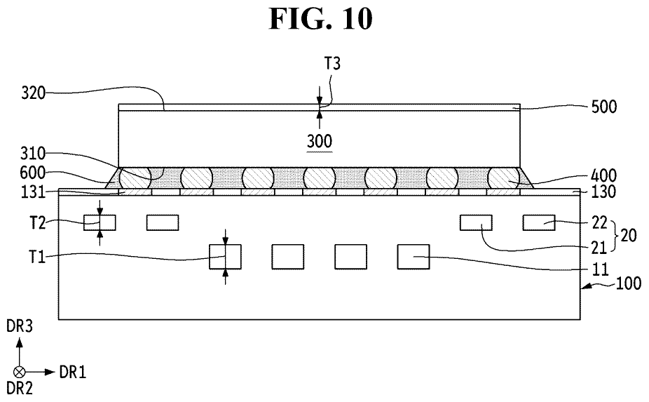

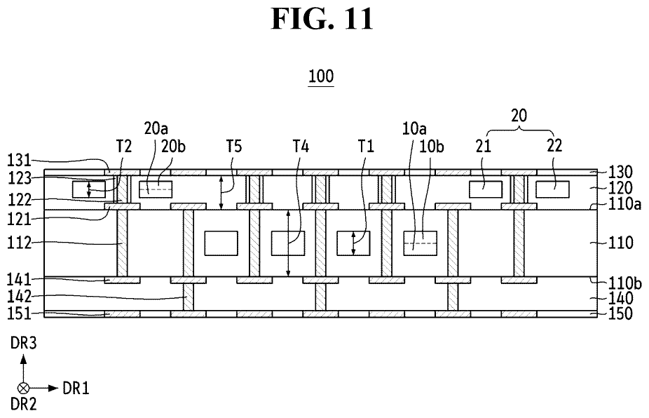

FIGS. 10 and 11 are cross-sectional side views illustrating a semiconductor package according to some embodiments of the present disclosure. Specifically, FIG. 10 is a cross-sectional side view of a semiconductor package according to some embodiments of the present disclosure. FIG. 11 is a cross-sectional side view of a substrate of the semiconductor package according to some embodiments of the present disclosure. For convenience of description, duplicate contents with respect to the semiconductor package described herein and shown with reference to FIGS. 1 to 9 will be briefly described or descriptions thereof may be omitted, and differences therebetween will be described.

Referring to FIGS. 10 and 11, the semiconductor package according to some embodiments of the present disclosure may include the plurality of first magnets 10 and the plurality of second magnets 20. Each of the first magnets 10 may not overlap with each of the second magnets 20 in the third direction DR3. In FIG. 10, the plurality of first magnets 10 is depicted as being positioned in a general center area of the substrate 100 while the plurality of second magnets 20 is depicted as being positioned in a general side area(s) of the substrate 100. However, embodiments of the present disclosure are not limited thereto. For example, in some embodiments, the plurality of first magnets 10 may be disposed in the general side area(s) of the substrate 100, and the plurality of second magnet 20 may be disposed in the general center area of the substrate 100. In another example, in some embodiments, the plurality of first magnets 10 and the plurality of second magnets 20 may be arranged in a zigzag pattern in the first direction DR1.

The plurality of first magnets 10 may have a first thickness T1. The plurality of second magnet 20 may have a second thickness T2. An influence (effect) of the magnetic force of the plurality of first magnets 10 on the magnetic layer 500 and an influence (effect) of the magnetic force of the plurality of second magnets 20 on the magnetic layer 500 need to be equal to each other. Since the plurality of first magnets 10 may be positioned farther from the magnetic layer 500 than the plurality of second magnets 20, the first thickness T1 of the plurality of first magnets 10 may be greater than the second thickness T2 of the plurality of second magnets 20.

Each of the first magnets 10 may include the first portion 10a and the second portion 10b. Each of the second magnets 20 may include the third portion 20a and the fourth portion 20b. The second portion 10b may reside closer to the magnetic layer 500 than the first portion 10a. The fourth portion 20b may reside closer to the magnetic layer 500 than the third portion 20a. The end of the second portion 10b of each of the first magnets 10 has a second magnetic polarity. The end of the fourth portion 20b of each of the second magnets 20 has a fourth magnetic polarity. In some embodiments, the second magnetic polarity and the fourth magnetic polarity have the same magnetic polarity. For example, in some embodiments, the second magnetic polarity and the fourth magnetic polarity may both be north (N) poles.

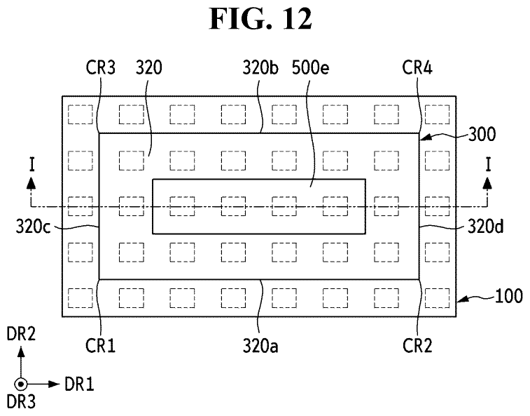

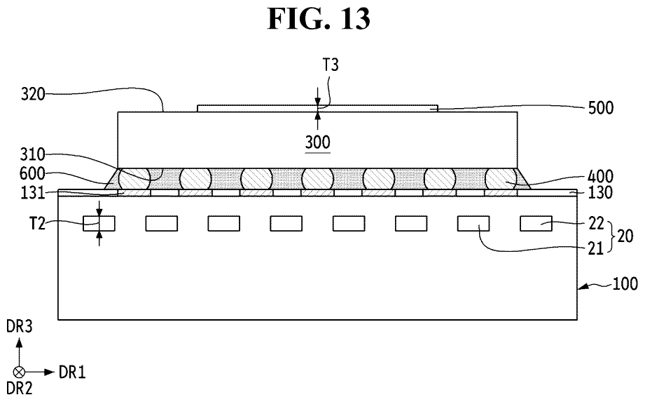

FIGS. 12 and 13 illustrate a semiconductor package according to some embodiments. Specifically, FIG. 12 is a plan view of a semiconductor package according to some embodiments of the present disclosure. FIG. 13 is a cross-sectional side view of a semiconductor package according to some embodiments of the present disclosure. For convenience of description, duplicate contents with respect to the semiconductor package described herein and shown with reference to FIGS. 1 to 4 will be briefly described or descriptions thereof may be omitted, and differences therebetween will be described.

Referring to FIGS. 12 and 13, in some embodiments, the magnetic layer 500 may be disposed in a general center area of the fourth surface 320 of the semiconductor chip 300 in a plan view. The magnetic layer 500 may cover at least a portion of the fourth surface 320 of the semiconductor chip 300. A width of the magnetic layer 500 in the first direction DR1 may be less than a width of the semiconductor chip 300 in the first direction DR1.

In some embodiments, the magnetic layer 500 may include the fifth magnetic layer 500e. In some embodiments, the magnetic layer 500 may not include the first magnetic layer 500a, the second magnetic layer 500b, the third magnetic layer 500c, and the fourth magnetic layer 500d. In some embodiments, the magnetic layer 500 may not include the first connection magnetic layer 510a, the second connection magnetic layer 510b, the third connection magnetic layer 510c, and the fourth connection magnetic layer 510d.

In some embodiments, when the magnetic layer 500 is positioned in the general center area of the semiconductor chip in a plan view, the semiconductor package may be able to control the warpage of the semiconductor chip 300 into the upward convex shape (i.e., the frown shape) from the substrate 100.

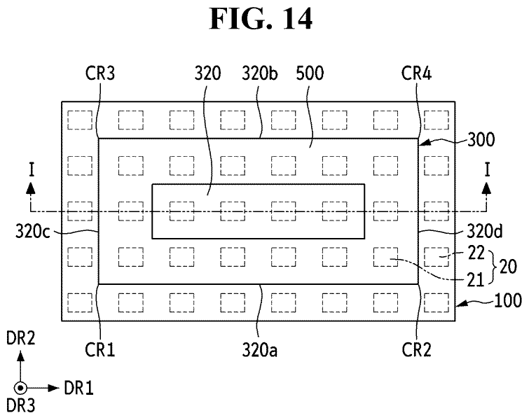

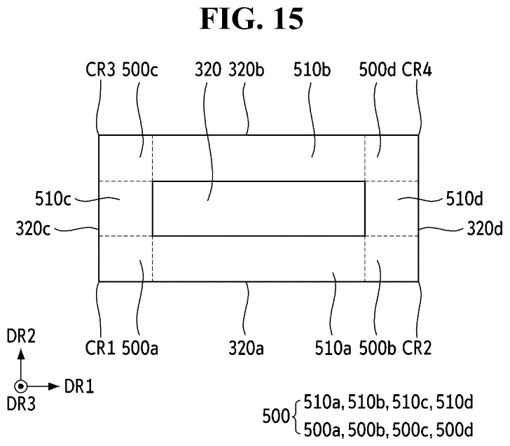

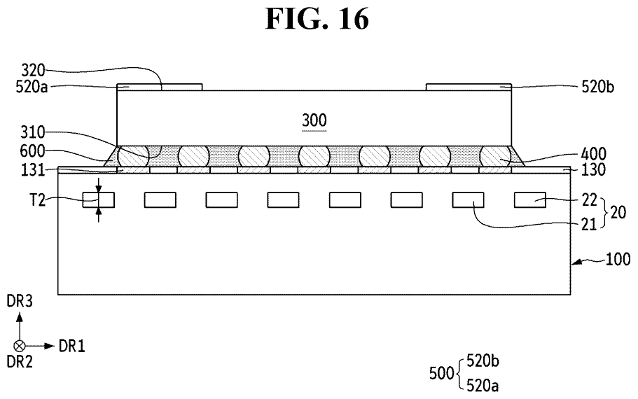

FIGS. 14 to 16 illustrate a semiconductor package according to some embodiments of the present disclosure. Specifically, FIG. 14 is a plan view of the semiconductor package according to some embodiments of the present disclosure. FIG. 15 is a plan view of the semiconductor chip of the semiconductor package according to some embodiments of the present disclosure. FIG. 16 is a cross-sectional side view of the semiconductor package according to some embodiments of the present disclosure. For convenience of description, duplicate contents with respect to the semiconductor package described herein and shown with reference to FIGS. 1 to 4 will be briefly described or descriptions thereof may be omitted, and differences therebetween will be described.

Referring to FIGS. 14 to 16, in some embodiments, the magnetic layer 500 may extend along a perimeter of the fourth surface 320 of the semiconductor chip 300. The magnetic layer 500 may have a rectangular ring shape in a plan view.

In some embodiments, the magnetic layer 500 may include the first magnetic layer 500a, the second magnetic layer 500b, the third magnetic layer 500c, and the fourth magnetic layer 500d. In some embodiments, the magnetic layer 500 may include the first connection magnetic layer 510a, the second connection magnetic layer 510b, the third connection magnetic layer 510c, and the fourth connection magnetic layer 510d. In some embodiments, the magnetic layer 500 may not include the fifth magnetic layer 500e.

As shown in the cross-sectional side view, the magnetic layer 500 may include a first sub-magnetic layer 520a and a second sub-magnetic layer 520b that are spaced apart from each other in the first direction DR1. In some embodiments, the first sub-magnetic layer 520a may correspond to the third connection magnetic layer 510c. In some embodiments, the second sub-magnetic layer 520b may correspond to the fourth connection magnetic layer 510d.

In some embodiments, as the magnetic layer 500 extends along an edge of the semiconductor chip 300, the semiconductor package may be able to control the warpage of the semiconductor chip 300 into the downward convex shape (i.e., the smile shape) from the substrate 100 (see, e.g., FIG. 5).

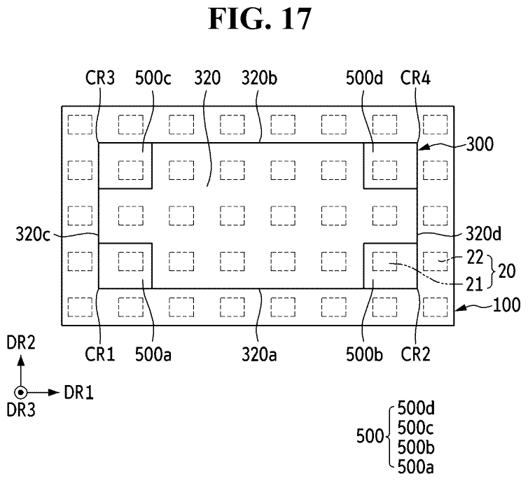

FIG. 17 illustrates a semiconductor package according to some embodiments of the present disclosure. Specifically, FIG. 17 is a plan view of a semiconductor package according to some embodiments of the present disclosure. For convenience of description, duplicate contents with respect to the semiconductor package described herein and shown with reference to FIGS. 1 to 4 will be briefly described or descriptions thereof may be omitted, and differences therebetween will be described.

Referring to FIG. 17, in some embodiments, the magnetic layer 500 may be disposed on each of corners (CR1, CR2, CR3, CR4) of the fourth surface 320 of the semiconductor chip 300. In some embodiments, the magnetic layer 500 may include the first magnetic layer 500a, the second magnetic layer 500b, the third magnetic layer 500c, and the fourth magnetic layer 500d. In some embodiments, the magnetic layer 500 may not include the first connection magnetic layer 510a, the second connection magnetic layer 510b, the third connection magnetic layer 510c, and the fourth connection magnetic layer 510d. In some embodiments, the magnetic layer 500 may not include the fifth magnetic layer 500e.

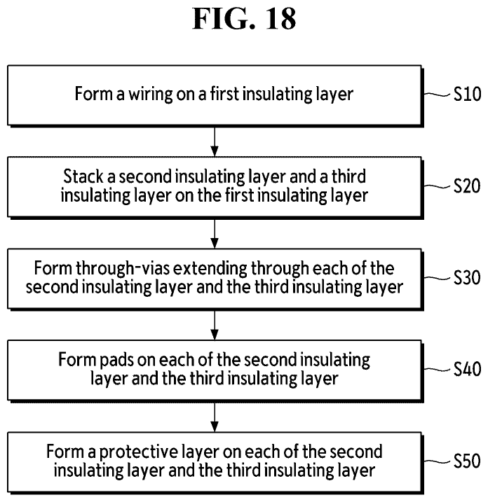

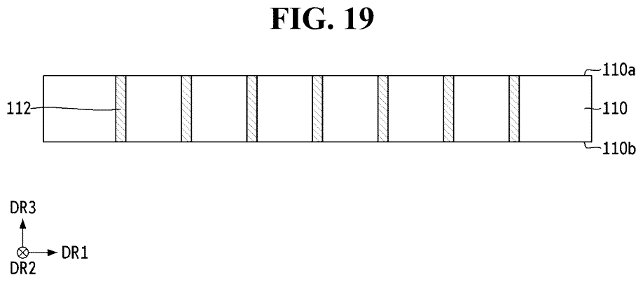

FIG. 18 is a flow chart illustrating a method for manufacturing a substrate according to some embodiments of the present disclosure. FIGS. 19 to 25 illustrate intermediate structures corresponding to intermediate steps of a method for manufacturing a substrate according to some embodiments of the present disclosure. For convenience of description, duplicate contents with respect to the semiconductor package described herein and shown with reference to FIGS. 1 to 4 will be briefly described or descriptions thereof may be omitted.

Referring to FIGS. 18 to 21, in some embodiments, a method of the present disclosure includes forming a wiring on the first insulating layer and the first through-via [Block S10].

First, referring to FIG. 19, the first insulating layer 110 and the plurality of first through-vias 112 extending through the first insulating layer 110 are provided. The first insulating layer 110 includes the first surface 110a and the second surface 110b that are opposite to each other in the third direction DR3. Opposing upper and lower surfaces of each of the plurality of first through-vias 112 are exposed to an outside of the first insulating layer 110.

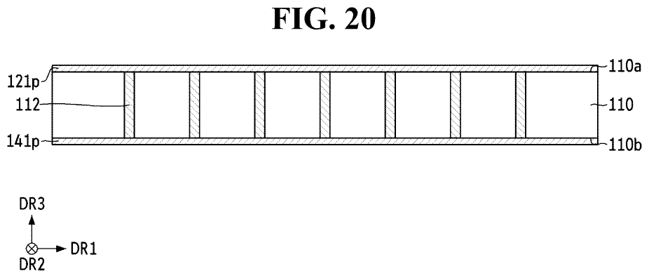

Next, referring to FIG. 20, a first wiring layer 121p and a second wiring layer 141p are formed on the first insulating layer 110 and the plurality of first through-vias 112. Specifically, the first wiring layer 121p is formed on the first surface 110a of the first insulating layer 110 and the upper surfaces of each of the first through-vias 112. The first wiring layer 121p covers at least a portion of the first surface 110a of the first insulating layer 110 and each of the upper surfaces of the first through-vias 112. The second wiring layer 141p is formed on the second surface 110b of the first insulating layer 110 and each of the lower surfaces of the first through-vias 112. The second wiring layer 141p covers at least a portion of the second surface 110b of the first insulating layer 110 and each of the lower surfaces of the first through-vias 112. In some embodiments, each of the first wiring layer 121p and the second wiring layer 141p may include copper (Cu).

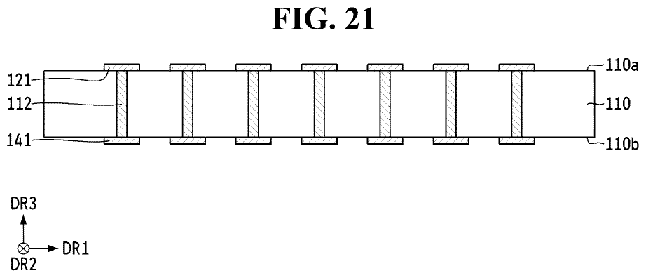

Next, referring to FIG. 21, the first wiring 121 and the second wiring 141 are formed on the first insulating layer 110 and the plurality of first through-vias 112. Specifically, the first wiring 121 is formed by removing a portion of the first wiring layer 121p. The first wiring 121 is formed on the first surface 110a of the first insulating layer 110 and the upper surface of each of the first through-vias 112. A portion of the first surface 110a of the first insulating layer 110 on which the first wiring 121 is not formed is exposed (i.e., free from the first wiring 121). The second wiring 141 is formed by removing a portion of the second wiring layer 141p. The second wiring 141 is formed on the second surface 110b of the first insulating layer 110 and the lower surface of each of the first through-vias 112. A portion of the second surface 110b of the first insulating layer 110 on which the second wiring 141 is not formed is exposed (i.e., free from the second wiring 141).

In some embodiments, the first wiring 121 may be formed through a process of patterning the first wiring layer 121p using a hard mask. In some embodiments, the second wiring 141 may be formed through a process of patterning the second wiring layer 141p using a hard mask.

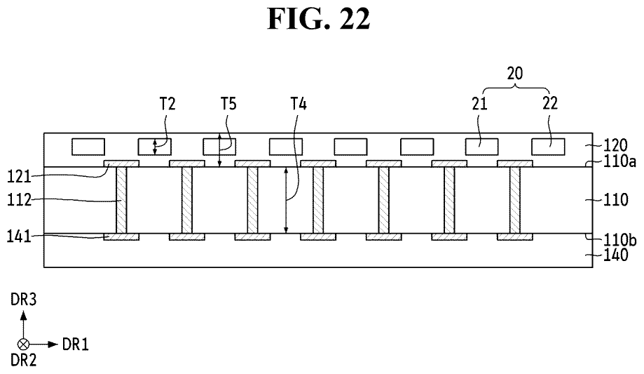

Referring to FIG. 18 and FIG. 22, in some embodiments, a method of the present disclosure includes the second insulating layer and the third insulating layer being stacked on the first insulating layer [Block S20].

First, the second insulating layer 120 and the third insulating layer 140 are provided. The second insulating layer 120 is provided in a state where the plurality of second magnets 20 have been formed within the second insulating layer 120. The plurality of second magnets 20 are arranged and are spaced from each other in the first direction DR1 within the second insulating layer 120.

Subsequently, the second insulating layer 120 and the third insulating layer 140 are stacked on the first insulating layer 110 in the third direction DR3. Specifically, the second insulating layer 120 is stacked on the first surface 110a of the first insulating layer 110 and the first wiring 121. The second insulating layer 120 at least partially covers the exposed portions of the first surface 110a of the first insulating layer 110 and the first wiring 121. The third insulating layer 140 is stacked on the second surface 110b of the first insulating layer 110 and the second wiring 141. The third insulating layer 140 at least partially covers the exposed portions of the second surface 110b of the first insulating layer 110 and the second wiring 141.

In some embodiments, the second insulating layer 120 and the third insulating layer 140 may be stacked on the first insulating layer 110 in a pressing process.

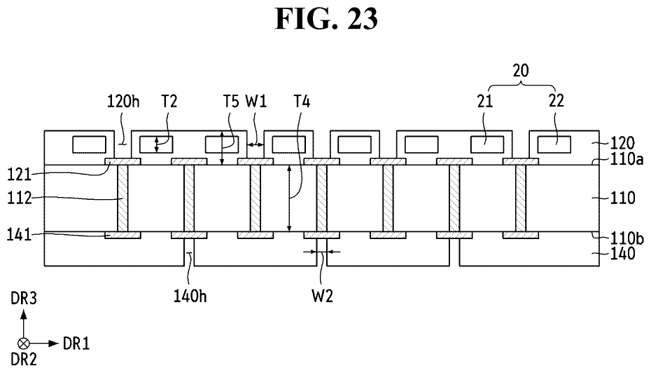

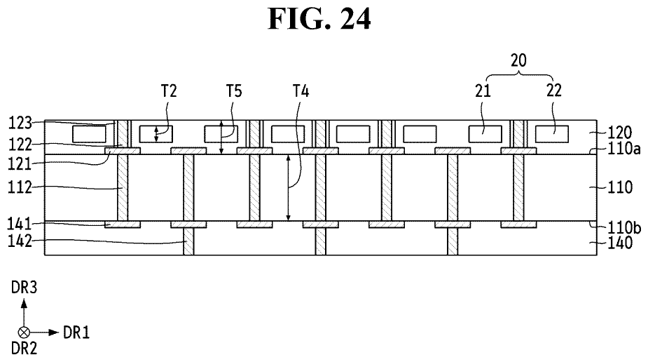

Referring to FIG. 18, FIG. 23, and FIG. 24, in some embodiments, a method of the present disclosure includes forming through-vias extending through each of the second insulating layer and the third insulating layer [Block S30].

First, referring to FIG. 23, a plurality of second through-via holes 120h and a plurality of third through-via holes 140h are formed in the second insulating layer 120 and the third insulating layer 140, respectively.

Specifically, the plurality of second through-via holes 120h is formed in the second insulating layer 120. Each of the second through-via holes 120h extends in the third direction DR3 from an upper surface of the second insulating layer 120 to an upper surface of a respective first wiring 121. Each of the second through-via holes 120h exposes at least a portion of the upper surface of each first wiring 121 (i.e., at least a portion of the upper surface of each first wiring 121 is free from the second insulating layer 120). In some embodiments, the plurality of second through-via holes 120h may not extend through the plurality of second magnets 20. Each second through-via hole 120h is spaced apart from the second magnets 20.

The plurality of third through-via holes 140h is formed in the third insulating layer 140. Each of the third through-via holes 140h extends in the third direction DR3 from the lower surface of the second insulating layer 120 to the lower surface of the respective second wiring 141. Each of the second through-via holes 120h exposes at least a portion of the lower surface of the second wiring 141.

In one example, each of the second through-via holes 120h has a first width W1, and each of the third through-via holes 140h has a second width W2. Each of the first width W1 and the second width W2 may refer to a width in the first direction DR1. In some embodiments, the first width W1 may be greater than the second width W2.

Next, referring to FIG. 24, the plurality of second through-vias 122 and the plurality of third through-vias 142 are formed in the plurality of second through-via holes 120h and the plurality of third through-via holes 140h, respectively. In some embodiments, the second shielding film 123 may be formed in each of the plurality of second through-via holes 120h.

Specifically, each of the second through-vias 122 is formed in the second through-via holes 120h. Each second through-via 122 fills at least a portion of the respective second through-via hole 120h. Each second through-via 122 covers at least a portion of the upper surface of the respective first wiring 121. The plurality of second through-vias 122 extends in the third direction DR3 from the upper surface of the first wiring 121 to the upper surface of the second insulating layer 120.

In some embodiments, the second shielding film 123 may be formed within each of the second through-via holes 120h. In some embodiments, the second shielding film 123 may at least partially surround each of the second through-vias 122. In some embodiments, the second shielding film 123 may extend along the side surface of each of the second through-vias 122 and in the third direction DR3. In some embodiments, the second shielding film 123 may cover at least a portion of the upper surface of the first wiring 121.

Each of the third through-vias 142 is formed within respective third through-via holes 140h. Each third through-via 142 fills at least a portion of the respective third through-via hole 140h. Each third through-via 142 covers at least a portion of the lower surface of the respective second wiring 141. The plurality of third through-vias 142 extends in the third direction DR3 from the lower surface of the second wiring 141 to the lower surface of the second insulating layer 120.

In one example, in some embodiments, a width of each of the second through-vias 122 in the first direction DR1 may be equal to a width of each of the third through-vias 142 in the first direction DR1.

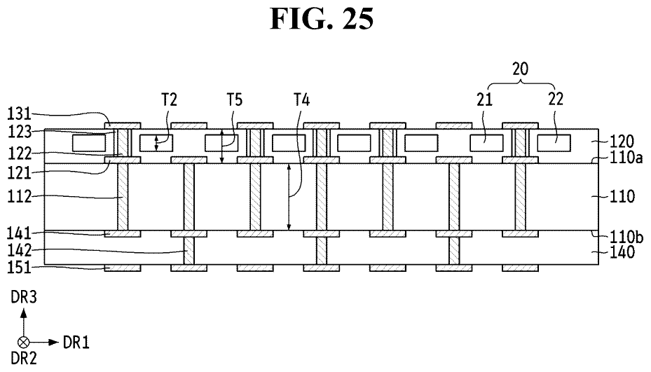

Referring to FIG. 18 and FIG. 25, in some embodiments, a method of the present disclosure includes forming pads on each of the second insulating layer and the third insulating layer [Block S40].

A plurality of first pads 131 are formed on the second insulating layer 120 and the plurality of second through-vias 122. The plurality of first pads 131 are arranged and spaced from each other in the first direction DR1. Each of the plurality of first pads 131 at least partially covers the upper surface of respective second through-vias 122. A plurality of second pads 151 are formed on the third insulating layer 140 and the plurality of third through-vias 142. Each of the plurality of second pads 151 are arranged and spaced from each other in the first direction DR1. Each of the plurality of second pads 151 at least partially covers the upper surface of respective third through-vias 142.

A process of forming the plurality of first pads 131 and the plurality of second pads 151 may be substantially the same as a process of forming the first wiring 121.

Referring to FIG. 18 and FIG. 4, in some embodiments, a method of the present disclose includes forming a protective layer on each of the second insulating layer and the third insulating layer [Block S50].

The first protective layer 130 is formed on the second insulating layer 120. At least a portion of the first protective layer 130 is formed between adjacent first pads 131. At least a portion of the first protective layer 130 covers an exposed portion of the upper surface of the second insulating layer 120 (i.e., free from the plurality of first pads 131). The first protective layer 130 fills a space between adjacent first pads 131.

The second protective layer 150 is formed on the third insulating layer 140. At least a portion of the second protective layer 150 is formed between adjacent second pads 151. At least a portion of the second protective layer 150 covers an exposed portion of the lower surface of the third insulating layer 140 (i.e., free from the plurality of second pads 141). The second protective layer 150 fills a space between adjacent second pads 151.

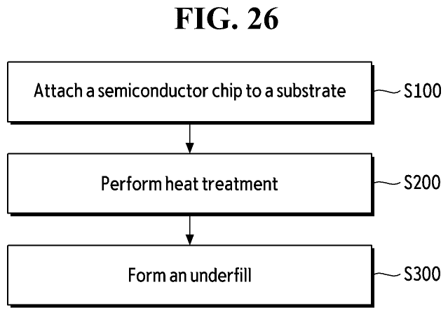

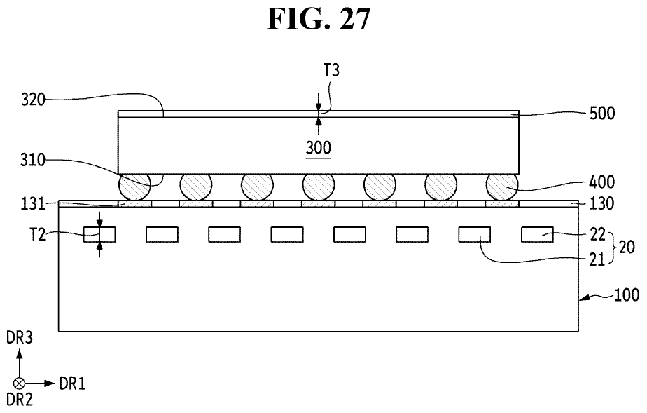

FIG. 26 is a flow chart illustrating a method of manufacturing a semiconductor package according to some embodiments of the present disclosure. FIGS. 27 to 29 illustrate intermediate structures corresponding to intermediate steps of a method for manufacturing a substrate according to some embodiments of the present disclosure. For convenience of description, duplicate contents with respect to the semiconductor package described herein and shown with reference to FIGS. 1 to 4 will be briefly described or descriptions thereof may be omitted.

Referring to FIGS. 26 and 27, in some embodiments, a method of the present disclosure includes attaching the semiconductor chip to the substrate [Block S100].

First, the substrate 100, the semiconductor chip 300, and the plurality of contact members 400 are provided. The semiconductor chip 300 includes the third surface 310 and the fourth surface 320. Each contact member 400 is provided in an attached state to the third surface 310 of the semiconductor chip 300.

Then, the semiconductor chip 300 is attached to the substrate 100. Specifically, each of the contact members 400 is attached to respective first pads 131 of the substrate 100. Each contact member 400 is in contact with the respective first pad 131.

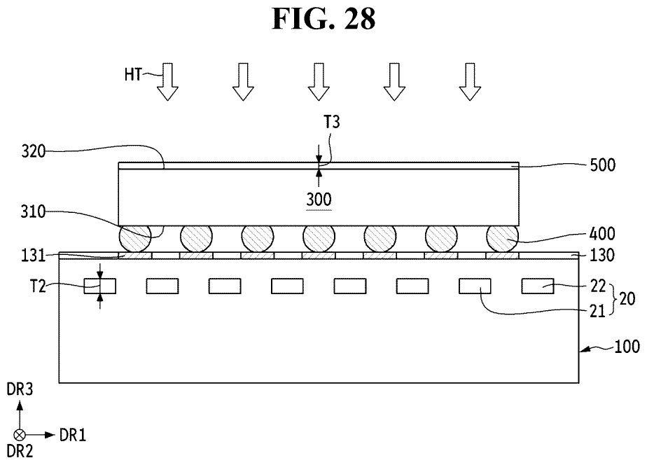

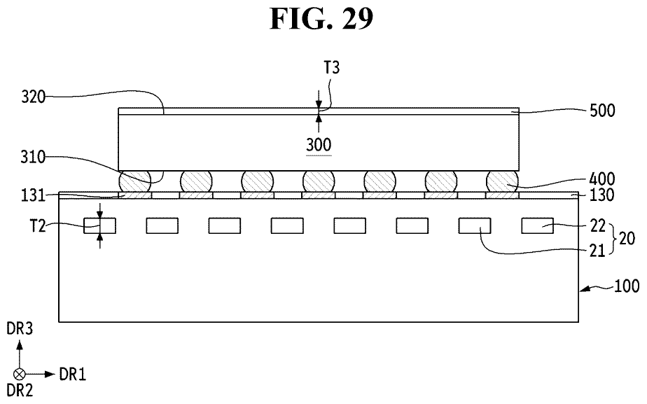

Referring to FIG. 26, FIG. 28, and FIG. 29, in some embodiments, a method of the present disclosure includes performing a heat treatment [Block S200].

First, referring to FIG. 28, in some embodiments, a heat treatment HT is performed on the substrate 100 and the semiconductor chip 300. The heat treatment HT is performed at a temperature at which the contact members 400 melt. For example, in some embodiments, the heat treatment HT may be performed at a temperature in the range of between about 200° C. to about 260° C. In some embodiments, the heat treatment HT may be a reflow process.

Referring to FIG. 29, in some embodiments, a contact area between each contact member 400 and corresponding first pad 131 may increase. As the contact area between the contact members 400 and the first pads 131 increases, an adhesion force between the substrate 100 and the semiconductor chip 300 may be improved.

In one example, warpage of the semiconductor chip 300 may occur during a cooling process of the contact members 400 after the heat treatment HT. Since the plurality of second magnets 20 is disposed in the substrate 100 and the magnetic layer 500 is disposed on the semiconductor chip 300, the plurality of second magnets 20 may pull the magnetic layer 500 under the magnetic force. Thus, the warpage of the semiconductor chip 300 may be controlled.

Referring to FIG. 26 and FIG. 3, in some embodiments, a method of the present disclosure includes forming the underfill [Block S300].

The underfill 600 is formed between the substrate 100 and the semiconductor chip 300. The underfill 600 fills the space between the substrate 100 and the semiconductor chip 300. The underfill 600 at least partially surrounds the side surfaces of the contact members 400. In some embodiments, the underfill 600 may be formed in a capillary underfill (CUF) or molded underfill (MUF) process.

In concluding the detailed description, those skilled in the art will appreciate that many variations and modifications may be made to the example embodiments described herein without substantially departing from the principles of the present disclosure. Therefore, the disclosed example embodiments of the present disclosure are used in a generic and descriptive sense only and not for purposes of limitation.

What is claimed is:

1. A semiconductor package comprising:
a substrate comprising an insulating layer and a through-via extending through the insulating layer;
a magnet within the insulating layer and spaced apart from the through-via;
a semiconductor chip on the substrate; and
a magnetic layer on the semiconductor chip and overlapping at least a portion of the magnet in a vertical direction relative to an upper surface of the substrate.

2. The semiconductor package of claim 1, wherein the insulating layer comprises a first insulating layer and a second insulating layer on the first insulating layer,
wherein the through-via comprises a first through-via extending through the first insulating layer and a second through-via extending through the second insulating layer,
wherein a thickness of the first insulating layer is greater than a thickness of the second insulating layer.

3. The semiconductor package of claim 2, wherein the magnet is within the second insulating layer.

4. The semiconductor package of claim 2, wherein the magnet comprises a first magnet within the first insulating layer and a second magnet within the second insulating layer,
wherein the first magnet is horizontally offset from the second magnet.

5. The semiconductor package of claim 4, wherein a thickness of the first magnet is greater than a thickness of the second magnet.

6. The semiconductor package of claim 1, wherein a thickness of the magnet is equal to or greater than a thickness of the magnetic layer.

7. The semiconductor package of claim 1, wherein the substrate further comprises a shielding film between the through-via and the magnet.

8. The semiconductor package of claim 1, wherein a width of the magnetic layer is less than a width of the semiconductor chip.

9. The semiconductor package of claim 1, wherein the magnetic layer comprises a first sub-magnetic layer and a second sub-magnetic layer spaced apart from each other.

10. The semiconductor package of claim 1, wherein the magnetic layer comprises a ferromagnetic material.

11. The semiconductor package of claim 1, wherein the substrate further comprises a contact member between the substrate and the semiconductor chip,
wherein the substrate further comprises a pad on the second insulating layer, and
wherein the contact member is in contact with the semiconductor chip and the pad.

12. The semiconductor package of claim 1, further comprising an underfill between the substrate and the semiconductor chip.

13. A semiconductor package comprising:
a substrate extending in a first direction and a second direction different from the first direction;
a plurality of magnets within the substrate and arranged along the first direction and the second direction;
a semiconductor chip on the substrate and extending in a third direction and a fourth direction different from the third direction; and
a magnetic layer on an upper surface of the semiconductor chip, and extending in the third direction and the fourth direction, wherein the magnetic layer is configured to be affected by a magnetic force of the plurality of magnets.

14. The semiconductor package of claim 13, wherein the upper surface of the semiconductor chip comprises:
a first edge extending in the third direction;
a third edge connected to the first edge and extending in the fourth direction; and
a first corner connecting the first edge and the third edge to each other,
wherein the magnetic layer extends from the first corner along the first edge and the third edge.

15. The semiconductor package of claim 14, wherein the upper surface of the semiconductor chip further comprises:
a second edge extending in the third direction and spaced apart from the first edge;
a fourth edge extending in the fourth direction and spaced apart from the third edge;
a second corner connecting the first edge and the fourth edge to each other;
a third corner connecting the second edge and the third edge to each other; and
a fourth corner connecting the second edge and the fourth edge to each other,
wherein the magnetic layer comprises:
a first magnetic layer extending from the first corner along the first edge and the third edge;
a second magnetic layer extending from the second corner along the first edge and the fourth edge;
a third magnetic layer extending from the third corner along the second edge and the third edge; and
a fourth magnetic layer extending from the fourth corner along the second edge and the fourth edge,
wherein the first magnetic layer, the second magnetic layer, the third magnetic layer, and the fourth magnetic layer are spaced apart from each other.

16. The semiconductor package of claim 15, wherein the magnetic layer comprises:
a first connection magnetic layer extending along the first edge and connecting the first magnetic layer and the second magnetic layer to each other;
a second connection magnetic layer extending along the second edge and connecting the third magnetic layer and the fourth magnetic layer to each other; and
a third connection magnetic layer extending along the third edge and connecting the first magnetic layer and the third magnetic layer to each other; and
a fourth connection magnetic layer extending along the fourth edge and connecting the second magnetic layer and the fourth magnetic layer to each other.

17. The semiconductor package of claim 13, wherein the upper surface of the semiconductor chip comprises a first edge and a second edge extending in the third direction and spaced apart from each other,
wherein the magnetic layer is spaced apart from the first edge and the second edge.

18. The semiconductor package of claim 17, wherein the upper surface of the semiconductor chip comprises a third edge and a fourth edge extending in the fourth direction and spaced apart from each other,
wherein the magnetic layer is spaced apart from the third edge and the fourth edge.

19. A semiconductor package comprising:
a substrate comprising a first insulating layer, a first through-via extending through the first insulating layer, a second insulating layer on the first insulating layer, a second through-via extending through the second insulating layer, a shielding film at least partially surrounding the second through-via, and a pad on the second insulating layer;
a magnet within the second insulating layer and spaced apart from the second through-via and the shielding film;
a semiconductor chip on the substrate;
a contact member between the substrate and the semiconductor chip and in contact with the semiconductor chip and the pad;
an underfill between the substrate and the semiconductor chip; and
a magnetic layer on the semiconductor chip and overlapping at least a portion of the magnet in a vertical direction relative to an upper surface of the substrate,
wherein a thickness of the first insulating layer is greater than a thickness of the second insulating layer.

20. The semiconductor package of claim 19, wherein a thickness of the magnet is equal to or greater than a thickness of the magnetic layer.
